(19) United States
(12) Patent Application Publication
(10) Pub. No.: US 2026/0090251 A1
(43) Pub. Date: Mar. 26, 2026

(54) LIGHT EMITTING DEVICE, DISPLAY DEVICE INCLUDING THE SAME, ELECTRONIC DEVICE INCLUDING THE DISPLAY DEVICE, AND METHOD FOR MANUFACTURING THE DISPLAY DEVICE

(71) Applicant: Samsung Display Co., Ltd., Yongin-si (KR)

(72) Inventors: Moon Jung BAEK, Yongin-si (KR); Young Min KIM, Yongin-si (KR); Hyun Woo NOH, Yongin-si (KR); Su Ji HAN, Yongin-si (KR)

(21) Appl. No.: 19/226,300

(22) Filed: Jun. 3, 2025

(30) Foreign Application Priority Data
Sep. 24, 2024 (KR) 10-2024-0129062

(51) Int. Cl. H10K 59/80; H10K 59/12; H10K 59/122

(52) U.S. Cl. CPC H10K 59/877; H10K 59/1201; H10K 59/122; H10K 59/80516

(57) ABSTRACT

A light emitting element includes a first electrode disposed in an emission area including a main emission area and a sub-emission area around (e.g., surrounding) the main emission area; a pixel defining layer disposed in a non-emission area around (e.g., surrounding) the emission area and extending into the sub-emission area; a scattering auxiliary electrode disposed on the pixel defining layer, overlapping the sub-emission area, and electrically connected to the first electrode; a light emitting layer disposed on the first electrode and the scattering auxiliary electrode; and a second electrode disposed on the pixel defining layer and the light emitting layer.

### CROSS-REFERENCE TO RELATED APPLICATION

The present application claims priority to and the benefit of Korean Patent Application No. 10-2024-0129062, filed on Sep. 24, 2024, in the Korean Intellectual Property Office, the entire content of which is incorporated herein by reference.

### BACKGROUND

### 1. Field

The present disclosure relates to a light emitting device, a display device including the same, an electronic device including the display device, and a method for manufacturing the display device.

### 2. Description of the Related Art

With the advance of information-oriented society, more and more demands are placed on display devices for displaying images in various ways. For example, display devices are employed in various electronic devices such as smartphones, digital cameras, laptop computers, navigation devices, and/or smart televisions.

The display device may be a flat panel display device such as a liquid crystal display device, a field emission display device and/or a light emitting display device. Examples of the light emitting display device may include an organic light emitting display device including organic light emitting elements, an inorganic light emitting display device including inorganic light emitting elements such as inorganic semiconductors, and a micro light emitting display device including micro light emitting elements.

The organic light emitting display device displays an image using light emitting elements, each including a light emitting layer made of an organic light emitting material. As described above, the organic light emitting display device implements image display using a self-light emitting element, and thus may have relatively enhance (e.g., better or superior) performance in power consumption, response speed, luminous efficiency, luminance, and/or wide viewing angle compared to other display devices.

One surface (e.g., one side) of the display device may be a display surface including a display area where an image is displayed. Emission areas, emitting light with respective luminance and colors, may be arranged in the display area.

The display device may include light emitting elements arranged in the emission areas.

### SUMMARY

Each light emitting element of the display device may include a first electrode and a second electrode opposite to (e.g., facing) each other, and a light emitting layer arranged therebetween.

Light from the light emitting layer may be reflected by the first electrode or the second electrode and emitted to the outside through the other electrode (e.g., the other one of the first electrode or the second electrode). For example, if (e.g., when) the first electrode reflects light, light from the light emitting layer may be emitted through the second electrode.

In this configuration, most of the light from the light emitting element may be emitted in a direction in which the first electrode and the second electrode face each other.

As a result, the luminance in a front direction facing the display surface of the display device is relatively high, while the luminance in a side or lateral direction oblique to the display surface of the display device is low. Therefore, the improvement of a viewing angle, representing a range within which the display device can be observed with a luminance above a threshold, may be limited.

Alternatively, if light from the light emitting element is scattered irregularly to improve the luminance in the side direction, the display quality of the display device may be significantly degraded as the amount of light emitted in the front direction may be reduced to less than half. For example, while the above discussed configuration ensures high luminance in the front direction, it limits the viewing angle due to lower luminance in the side directions. Attempts to scatter light irregularly to enhance side luminance may also degrade display quality by significantly reducing front luminance.

In view of the foregoing, aspects of the present disclosure are directed toward a light emitting element, a display device including the same, an electronic device including the display device, and a method for manufacturing the display device, which may improve the viewing angle without significantly degrading display quality by maintaining the amount of light in the front direction above a threshold.

However, aspects of the present disclosure are not restricted to the ones set forth herein. The above and other aspects of the present disclosure will become more apparent to one of ordinary skill in the art to which the present disclosure pertains by referencing the detailed description of the present disclosure given below.

According to one or more embodiments of the present disclosure, a light emitting element includes a first electrode in an emission area, the emission area including a main emission area and a sub-emission area around (e.g., surrounding) the main emission area; a pixel defining layer in a non-emission area around (e.g., surrounding) the emission area and extending into the sub-emission area; a scattering auxiliary electrode on the pixel defining layer, overlapping the sub-emission area, and electrically connected to the first electrode; a light emitting layer on the first electrode and the scattering auxiliary electrode; and a second electrode on the pixel defining layer and the light emitting layer.

The pixel defining layer contains a light-transmitting organic insulating material, and scattering particles dispersed in the organic insulating material. Each of the scattering particles is a metal oxide particle, a hollow silica particle, or a porogen. The metal oxide particle contains titanium oxide (TiO₂) and/or zirconium oxide (ZrO).

The pixel defining layer in the sub-emission area has an inclined surface that is sloped relative to the first electrode.

The scattering auxiliary electrode is on the inclined surface of the pixel defining layer, extends to the first electrode, and is in contact with at least a portion of the first electrode.

The scattering auxiliary electrode entirely covers the first electrode in the main emission area.

The first electrode includes a reflective portion configured to reflect light; and a roof portion on the reflective portion. The roof portion contains a crystalline transparent conductive material.

The scattering auxiliary electrode contains a transparent conductive material.

The pixel defining layer includes a light blocking portion in the non-emission area and containing a light-blocking organic material; and a scattering portion covering the light blocking portion and containing the organic insulating material and the scattering particles.

According to one or more embodiments of the present disclosure, a display device includes a substrate including emission areas and a non-emission area between the emission areas; a circuit layer on the substrate; and an element layer on the circuit layer. Each of the emission areas includes a main emission area and a sub-emission area around (e.g., surrounding) the main emission area. The element layer includes light emitting elements in the emission areas. The circuit layer includes light emitting pixel drivers electrically connected to the light emitting elements. The light emitting element in one of the emission areas includes a first electrode in the one emission area; a pixel defining layer in the non-emission area around (e.g., surrounding) the emission area and extending into the sub-emission area of the one emission area; a scattering auxiliary electrode on the pixel defining layer, overlapping the sub-emission area of the one emission area, and electrically connected to the first electrode; a light emitting layer on the first electrode and the scattering auxiliary electrode; and a second electrode on the pixel defining layer and the light emitting layer.

The pixel defining layer contains a light-transmitting organic insulating material, and scattering particles dispersed in the organic insulating material. Each of the scattering particles is a metal oxide particle, a hollow silica particle, or a porogen. The metal oxide particle contains titanium oxide (TiO₂) and/or zirconium oxide (ZrO).

The pixel defining layer in the sub-emission area includes an inclined surface that is sloped relative to the first electrode.

The scattering auxiliary electrode is on the inclined surface of the pixel defining layer, extends to the first electrode, is in contact with at least a portion of the first electrode, and contains a transparent conductive material.

The scattering auxiliary electrode entirely covers the first electrode in the main emission area.

The first electrode includes a reflective portion configured to reflect light; and a roof portion on the reflective portion. The roof portion contains a crystalline transparent conductive material.

The pixel defining layer includes a light blocking portion in the non-emission area and containing a light-blocking organic material; and a scattering portion covering the light blocking portion and containing the organic insulating material and the scattering particles.

According to one or more embodiments of the present disclosure, a method for manufacturing a display device includes preparing a substrate including emission areas and a non-emission area between the emission areas; disposing a circuit layer on the substrate; and disposing an element layer on the circuit layer. Each of the emission areas includes a main emission area and a sub-emission area around (e.g., surrounding) the main emission area. The disposing of the element layer includes disposing first electrodes in the emission areas; disposing a pixel defining layer in the non-emission area and the sub-emission areas of the emission areas; disposing, on the pixel defining layer, scattering auxiliary electrodes overlapping the sub-emission areas of the emission areas and electrically connected to the first electrodes; disposing light emitting layers overlapping the emission areas on the first electrodes and the scattering auxiliary electrodes; and disposing a second electrode on the pixel defining layer and the light emitting layers.

In the disposing of the pixel defining layer, the pixel defining layer contains a light-transmitting organic insulating material, and scattering particles dispersed in the organic insulating material. Each of the scattering particles is a metal oxide particle, a hollow silica particle, or a porogen. The metal oxide particle contains titanium oxide (TiO₂) and/or zirconium oxide (ZrO).

In the disposing of the pixel defining layer, portions of the pixel defining layer, which are arranged in the sub-emission areas of the emission areas, include inclined surfaces that are sloped relative to the first electrodes. In the disposing of the scattering auxiliary electrodes, the scattering auxiliary electrodes are on the inclined surfaces of the portions of the pixel defining layer, extend to the first electrodes, and contain a transparent conductive material. Each of the scattering auxiliary electrodes is in contact with at least a portion of each of the first electrodes.

In the disposing of the scattering auxiliary electrodes, the transparent conductive material covering the first electrodes and the pixel defining layer is selectively removed using a mask including transmission portions overlapping the emission areas.

The disposing of the pixel defining layer includes disposing a light blocking portion containing a light-blocking organic material in the non-emission area; and disposing a scattering portion covering the light blocking portion in the non-emission area and the sub-emission areas of the emission areas. The scattering portion contains the organic insulating material and the scattering particles.

The light emitting element according to one or more embodiments includes a first electrode arranged in an emission area, a pixel defining layer arranged in a non-emission area and extending into a sub-emission area around (e.g., surrounding) a main emission area of the emission area, and a scattering auxiliary electrode arranged on the pixel defining layer, overlapping the sub-emission area, and electrically connected to the first electrode.

According to one or more embodiments, the pixel defining layer contains a light-transmitting organic insulating material, and scattering particles dispersed in the organic insulating material.

The scattering auxiliary electrode may contain a transparent conductive material.

Accordingly, light generated from a portion of a light emitting layer between the first electrode and the second electrode may be reflected by the first electrode and emitted in the front direction where the first electrode and the second electrode face each other.

In addition, light generated from another portion of the light emitting layer between the scattering auxiliary electrode and the second electrode may be reflected in an irregular (e.g., random) direction by the scattering particles of the pixel defining layer and emitted in a side direction oblique to the front direction.

For example, light generated in the main emission area, where the first electrode and the second electrode face each other with the light emitting layer interposed therebetween, may be emitted in the front direction, and light generated in the sub-emission area, where the scattering auxiliary electrode is arranged, may be emitted in the side direction.

Therefore, by maintaining the proportion of the main emission area within the emission area above a threshold, the light amount in the front direction may be maintained above the threshold with respect to the total light amount of the light emitting element, while a portion of the light of the light emitting element may also be emitted in the side direction by the scattering auxiliary electrode of the sub-emission area. For example, this design ensures that the display device achieves a balanced light distribution, enhancing the overall viewing experience. The main emission area provides sufficient brightness for direct viewing, while the sub-emission area, with the scattering auxiliary electrode, contributes to a wider viewing angle by emitting light in various directions. This combination allows for improved visibility and display quality from different angles, making the display device more versatile and user-friendly. By maintaining the proportion of the main emission area within the emission area above a threshold, the light amount in the front direction is ensured to be above a certain level, providing adequate brightness for direct viewing. Concurrently, the scattering auxiliary electrode in the sub-emission area emits light in the side direction, enhancing the viewing angle without significantly degrading the display quality. This balanced light distribution is for achieving a high-quality display that is visible from multiple angles.

By including such a light emitting element, the viewing angle of the display device may be improved without significantly degrading the display quality of the display device.

It should be noted that aspects and/or effects of the present disclosure are not limited to those described above and other aspects and/or effects of the present disclosure will be apparent to those skilled in the art from the following descriptions.

### BRIEF DESCRIPTION OF THE DRAWINGS

The above and other aspects and features of the present disclosure will become more apparent by describing in more detail embodiments thereof with reference to the attached drawings, in which:

FIG. 1 is a perspective view illustrating a display device according to one or more embodiments;

FIG. 2 is a plan view illustrating the display device of FIG. 1;

FIG. 3 is a cross-sectional view taken along the line A-A′ of FIG. 2;

FIG. 4 is a layout diagram showing the substrate and the circuit layer of FIG. 3;

FIG. 5 is an equivalent circuit diagram showing the light emitting pixel driver of FIG. 4;

FIG. 6 is a layout diagram illustrating part B of FIG. 2;

FIG. 7 is a cross-sectional view taken along the line C-C′ of FIG. 6 according to one or more embodiments;

FIG. 8 is an enlarged view showing part D of FIG. 7;

FIG. 9 is a diagram illustrating the light emission direction of the light emitting element of FIG. 7;

FIGS. 10, 11, 12 and 13 are cross-sectional views taken along the line C-C′ of FIG. 6 according to embodiments, respectively;

FIG. 14 is a flowchart illustrating a method for manufacturing the display device according to one or more embodiments;

FIG. 15 is a flowchart illustrating a step (e.g., act or task) of disposing an element layer of FIG. 14;

FIGS. 16 to 23 are process diagrams illustrating some steps (e.g., acts or tasks) of FIG. 15 according to the embodiments illustrated in FIG. 7;

FIGS. 24 and 25 are process diagrams illustrating a step (e.g., act or task) of disposing the scattering auxiliary electrode of FIG. 15, according to the embodiments illustrated in FIG. 11; and

FIGS. 26 and 27 are process diagrams illustrating a step (e.g., act or task) of disposing the pixel defining layer of FIG. 15 according to the embodiments illustrated in FIG. 12.

FIG. 28 is a block diagram of an electronic device according to one or more embodiments of the present disclosure.

FIG. 29 is a schematic diagram of electronic devices according to one or more suitable embodiments of the present disclosure.

### DETAILED DESCRIPTION

Example embodiments will now be described more fully hereinafter with reference to the accompanying drawings. The present disclosure may, however, be embodied in different forms and should not be construed as limited to the example embodiments set forth herein. The same reference numbers indicate the same components throughout the disclosure. In the accompanying drawings, the thickness of layers and regions may be exaggerated for clarity.

Some of the parts which are not associated with the description may not be provided in order to describe embodiments of the disclosure.

It will also be understood that if (e.g., when) a layer is referred to as being “on” another layer or substrate, it can be directly on the other layer or substrate, or intervening layers may also be present. In contrast, if (e.g., when) an element is referred to as being “directly on” another element, there may be no intervening elements present. For example, this refers to that when an element is described as being “directly on” another element, it is in direct contact with that element without any layers or materials in between.

Further, the phrase “in a plan view” refers to if (e.g., when) an object portion is viewed from above, and the phrase “in a schematic cross-sectional view” refers to if (e.g., when) a schematic cross-section taken by vertically cutting an object portion is viewed from the side. The terms “overlap” and “overlapped” refer to that a first object may be above or below or to a side of a second object, and vice versa. Additionally, the term “overlap” may include layer, stack, face or opposite to (e.g., facing), extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “opposite to (e.g., facing)” may refer to that a first object may directly or indirectly oppose a second object. In a case in which a third object intervenes between a first and second objects, the first and second objects may be understood as being indirectly opposed to one another, although still opposite to (e.g., facing) each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” the other device. Accordingly, the illustrative term “below” may include both (e.g., simultaneously) the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to the other element, or “electrically connected” or “electrically coupled” to the other element with one or more intervening elements interposed therebetween. It will be further understood that if (e.g., when) the terms “comprises,” “including,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof. For example, it will be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Additionally, the terms “comprise(s)/comprising,” “include(s)/including,” “have/has/having”, or other similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

It will be understood that, although the terms “first,” “second,” “third,” and/or the like may be used herein to describe one or more suitable elements, these elements should not be limited by these terms. These terms are used to distinguish one element from another element or for the convenience of description and explanation thereof. For example, if (e.g., when) “a first element” is discussed in the description, it may be termed “a second element” or “a third element,” and “a second element” and “a third element” may be termed in a similar manner without departing from the teachings herein.

The terms “about” or “approximately” as used herein are used as terms of approximation and not as terms of degree, and are inclusive of the stated value and means within an acceptable range of deviation for the particular value as determined by one of ordinary skill in the art, considering the measurement in question and the error associated with measurement of the particular quantity (for example, the limitations of the measurement system). For example, “about” may refer to within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to refer to “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from among the group of” for the purpose of its meaning and interpretation. For example, “at least one of A and B” may be understood to refer to “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

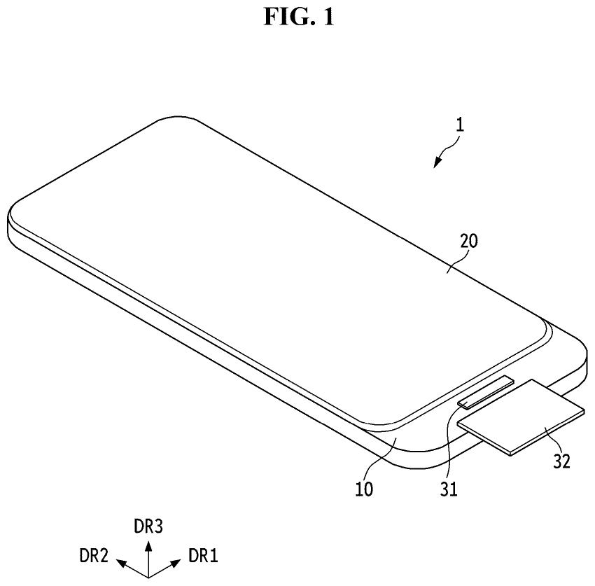

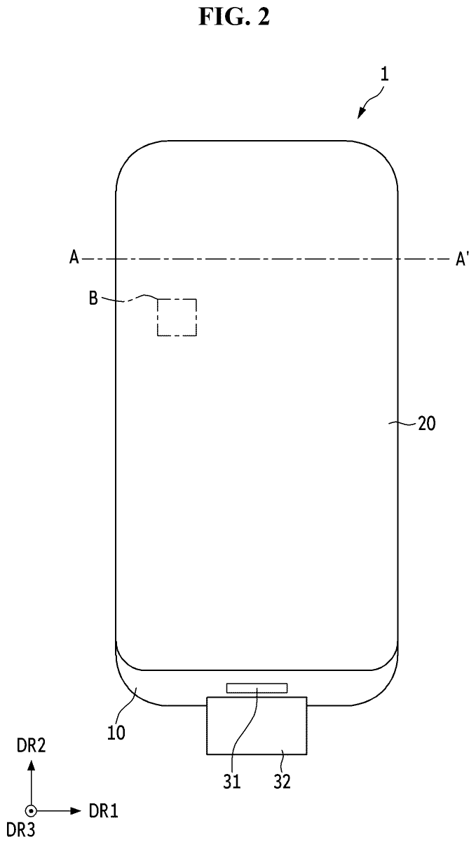

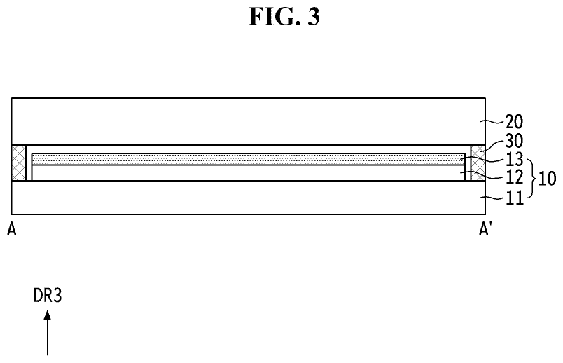

FIG. 1 is a perspective view illustrating a display device according to one or more embodiments. FIG. 2 is a plan view illustrating the display device of FIG. 1. FIG. 3 is a cross-sectional view taken along the line A-A′ of FIG. 2.

Referring to FIGS. 1 and 2, a display device 1, which is a device for displaying a moving image or a still image, may be used as a display screen of one or more suitable devices, such as a television, a laptop computer, a monitor, a billboard and/or an Internet-of-Things (IOT) device, as well as portable electronic devices such as a mobile phone, a smartphone, a tablet personal computer (PC), a smart watch, a watch phone, a mobile communication terminal, an electronic notebook, an electronic book, a portable multimedia player (PMP), a navigation device and/or an ultra-mobile PC (UMPC).

The display device 1 may be a light emitting display device such as an organic light emitting display using an organic light emitting diode, a quantum dot light emitting display including a quantum dot light emitting layer, an inorganic light emitting display including an inorganic semiconductor, and/or a micro light emitting display using a micro or nano light emitting diode (LED). In the following description, it is assumed that the display device 1 is an organic light emitting display device. However, the present disclosure is not limited thereto, and may be applied to a display device including an organic insulating material, an organic light emitting material, and a metal material.

The display device 1 may have a flat plate shape (e.g., in a form of plates) in the plane of a first direction DR1 and a second direction DR2 (e.g., in a plan view), but the present disclosure is not limited thereto. For example, the display device 1 may include a curved portion formed at the left and/or right end and having a constant curvature or a varying curvature. In addition, the display device 1 may be formed flexibly so that it can be curved, bent, folded, and/or rolled.

The display surface of the display device 1 may have a rectangular shape with short sides in the first direction DR1 and long sides in the second direction DR2. However, this is merely an example, and the display surface of the display device 1 may be implemented in one or more suitable shapes.

For example, the display surface may have a shape in which the corner, where the short side in the first direction DR1 and the long side in the second direction DR2 meet, is rounded with a set or predetermined curvature. In one or more embodiments, the display surface may have a shape such as a polygon, a circle, or an ellipse.

The display device 1 may include a first substrate 10 that emits light, and a second substrate 20 that faces the first substrate 10 in a third direction DR3 and transmits light.

Each of the first substrate 10 and the second substrate 20 may have a flat plate shape (e.g., in a form of plates) in the plane of the first direction DR1 and the second direction DR2.

Although FIG. 1 illustrates that the first substrate 10 has a flat plate shape (e.g., in a form of plates), the present disclosure is not limited thereto. For example, the first substrate 10 may have a shape in which at least one of the long sides in the second direction DR2 is curved. In one or more embodiments, the first substrate 10 may be provided to be flexible so that it can be curved, bent, folded, and/or rolled.

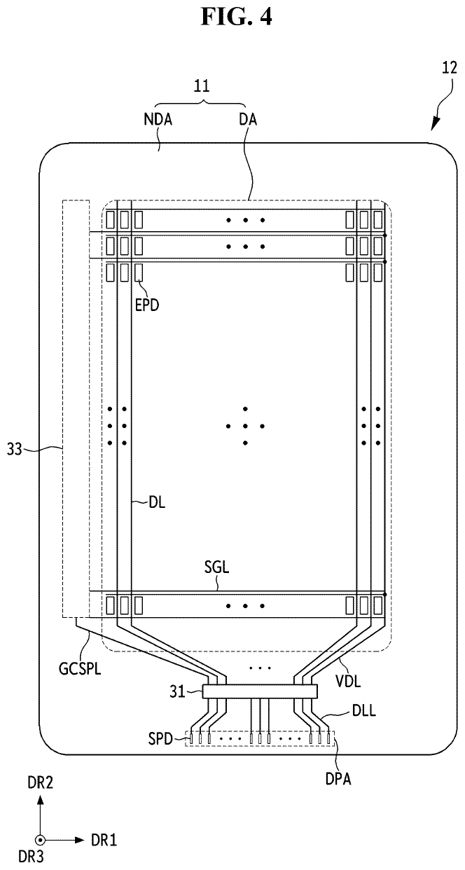

The display device 1 may further include a display driving circuit 31 for supplying a data signal to data lines DL (see FIG. 4) of a circuit layer 12 (see FIG. 3) of the first substrate 10, and a circuit board 32 for supplying various signals and powers to the circuit layer 12 (see FIG. 3) of the first substrate 10 and the display driving circuit 31.

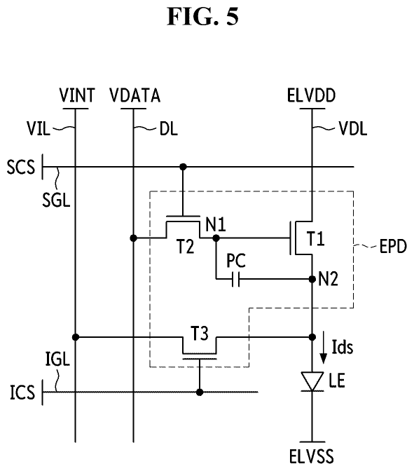

The display driving circuit 31 or the circuit board 32 may supply a first power ELVDD (see FIG. 5) to a first power line VDL (see FIG. 4) of the first substrate 10.

The display driving circuit 31 may supply a scan control signal to a gate driver 33 (see FIG. 4) embedded in the first substrate 10.

The display driving circuit 31 may be provided as an integrated circuit (IC).

The integrated circuit chip of the display driving circuit 31 may be directly mounted on the first substrate 10 by a chip on glass (COG) method, a chip on plastic (COP) method, or an ultrasonic bonding method. In this case, as shown in FIG. 2, the integrated circuit chip of the display driving circuit 31 may be arranged in a region of the first substrate 10 that does not overlap the second substrate 20.

In one or more embodiments, the integrated circuit chip of the display driving circuit 31 may be mounted on the circuit board 32.

The circuit board 32 may include an anisotropic conductive film. The circuit board 32 may be a flexible printed circuit board, a printed circuit board, or a flexible film such as a chip on film.

The circuit board 32 may be attached to and electrically connected to signal pads SPD (see FIG. 4) arranged in a non-display area NDA of the first substrate 10.

Referring to FIG. 3, the first substrate 10 may include a substrate 11, a circuit layer 12 arranged on the substrate 11, and an element layer 13 arranged on the circuit layer 12.

The substrate 11 may include a display area DA from which light is emitted and the non-display area NDA arranged around the display area DA.

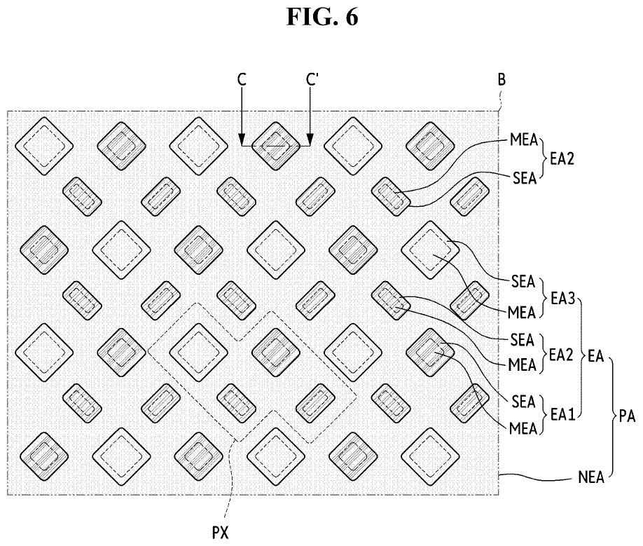

Emission areas EA (see FIG. 6) may be arranged in the display area DA.

The element layer 13 may include light emitting elements LE (see FIG. 5) arranged in the emission areas EA.

The circuit layer 12 may include light emitting pixel drivers EPD (see FIG. 4) electrically connected to the light emitting elements LE.

The display driving circuit 31 may generate a data signal VDATA (see FIG. 5) according to an image signal.

The light emitting pixel drivers EPD may be to transmit a driving current, having a magnitude corresponding to the data signal VDATA (see FIG. 5) supplied from the display driving circuit 31, to the light emitting elements LE.

The light emitting elements LE may be to emit light with a luminance corresponding to a driving current Ids (see FIG. 5) supplied from the light emitting pixel drivers EPD.

Accordingly, the display device 1 may provide a function of displaying an image.

In one or more embodiments, the display device 1 may further include a touch sensor for detecting coordinates of a point touched by a user on the display surface from which light for image display is emitted.

The touch sensor may be attached to one surface of the second substrate 20, or may be arranged between the first substrate 10 and the second substrate 20.

The second substrate 20 may (e.g., serve to) provide rigidity to defend against external physical and electrical impacts. The second substrate 20 may be made of a transparent material having insulating properties and rigidity.

According to one or more embodiments, the display device 1 may include a sealing layer 30 that bonds the first substrate 10 and the second substrate 20 together.

The sealing layer 30 may be arranged in the non-display area NDA between the first substrate 10 and the second substrate 20.

The display device 1 may include a filling layer that fills a space between the first substrate 10 and the second substrate 20.

FIG. 4 is a layout diagram showing the substrate and the circuit layer of FIG. 3.

Referring to FIG. 4, the substrate 11 of the display device 1 may include the display area DA that emits light for image display, and the non-display area NDA around (e.g., surrounding) the display area DA.

The circuit layer 12 may include the light emitting pixel drivers EPD arranged in the first direction DR1 and the second direction DR2 in the display area DA, and wires for supplying a signal or power to the light emitting pixel drivers EPD.

The wires of the circuit layer 12 may include a scan gate line SGL for transmitting a scan signal SCS (see FIG. 5), the data line DL for transmitting the data signal VDATA (see FIG. 5), and the first power line VDL for transmitting the first power ELVDD (see FIG. 5).

The scan gate line SGL may extend in the first direction DR1.

The data line DL may extend in the second direction DR2.

The first power line VDL may extend in one of the first direction DR1 or the second direction DR2. In one example, the first power line VDL may extend in the second direction DR2, similarly to the data line DL. For example, the first power line VDL may extend in either the first direction (DR1) or the second direction (DR2). In one specific example, it extends in the second direction (DR2), just like the data line (DL). In another example, a portion of the first power line VDL may cross both the first direction DR1 and the second direction DR2 while another portion of the first power line VDL may extend in the first direction DR1 or the second direction DR2.

The non-display area NDA may include a display pad area DPA arranged adjacent to the edge of the substrate 11.

The circuit layer 12 may further include the signal pads SPD arranged in the display pad area DPA of the non-display area NDA and electrically connected to the circuit board 32 (see FIGS. 1 and 2), and data connection lines DLL that electrically connect some of the signal pads SPD to the display driving circuit 31.

The circuit layer 12 may include a gate driver 33 arranged in a portion of the non-display area NDA.

The gate driver 33 may be electrically connected to the display driving circuit 31 or at least one signal pad SPD through at least one gate control supply line GCSPL.

The gate driver 33 may output the scan signal SCS to the scan gate lines SGL based on a gate control signal, a gate level power, and/or the like supplied through at least one gate control supply line GCSPL.

The gate driver 33 may face one side of the display area DA in the first direction DR1. However, this is merely an example, and the gate driver 33 may be arranged in another portion of the non-display area NDA adjacent to the right side of the display area DA. In one or more embodiments, the gate driver 33 may be arranged on both sides (e.g., opposite sides) of the display area DA in the left and right directions.

FIG. 5 is an equivalent circuit diagram showing the light emitting pixel driver of FIG. 4.

Referring to FIG. 5, the light emitting pixel driver EPD may be electrically connected between a first power source ELVDD and the light emitting element LE, and the light emitting element LE may be electrically connected between the light emitting pixel driver EPD and a second power source ELVSS.

The light emitting element LE may be an organic light emitting diode (OLED) having an organic light emitting layer, a quantum dot light emitting diode (LED) including a quantum dot light emitting layer, a micro LED, or an inorganic LED having an inorganic semiconductor.

The second power source ELVSS may be at a voltage level lower than that of the first power source ELVDD.

For example, the anode electrode of the light emitting element LE may be electrically connected to the light emitting pixel driver EPD, and the cathode electrode of the light emitting element LE may be electrically connected to the second power source ELVSS.

The circuit layer 120 may include the scan gate line SGL for transmitting the scan signal SCS to the light emitting pixel drivers EPD, an initialization gate line IGL for transmitting an initialization control signal ICS to the light emitting pixel drivers EPD, the data line DL for transmitting the data signal VDATA to the light emitting pixel drivers EPD, an initialization voltage line VIL for transmitting an initialization voltage VINT to the light emitting pixel drivers EPD, and the first power line VDL for transmitting the first power ELVDD to the light emitting pixel drivers EPD.

The light emitting pixel driver EPD may include a first transistor T1 that generates a driving current of the light emitting element LE, and at least one capacitor (e.g., a first capacitor PC) and one or more additional transistors (e.g., a second transistor T2 and a third transistor T3) electrically connected to the first transistor T1.

The first transistor T1 may be electrically connected between the first power line VDL and the light emitting element LE.

The gate electrode of the first transistor T1 may be electrically connected to the second transistor T2 through a first node N1.

The first electrode of the first transistor T1 may be electrically connected to the first power line VDL.

The second electrode of the first transistor T1 may be electrically connected to the anode electrode of the light emitting element LE through a second node N2.

The second transistor T2 may be electrically connected between the data line DL and the first node N1.

The gate electrode of the second transistor T2 may be electrically connected to the scan gate line SGL. For example, the second transistor T2 may be turned on by the scan signal SCS of the scan gate line SGL.

When the second transistor T2 is turned on, the data signal VDATA of the data line DL may be transmitted to the gate electrode of the first transistor T1 through the first node N1.

Accordingly, a voltage difference, e.g., a gate-source voltage difference, between the gate electrode of the first transistor T1 and the first electrode of the first transistor T1 may correspond to a differential voltage between the first power source ELVDD and the data signal VDATA, and may be greater than the threshold voltage of the first transistor T1. As a result, a source-drain current Ids having a magnitude corresponding to the data signal VDATA may be generated between the first electrode and the second electrode of the first transistor T1 by the turned-on first transistor T1. The source-drain current Ids of the first transistor T1 may be supplied as a driving current to the light emitting element LE through the second node N2.

Accordingly, the driving current Ids of the magnitude corresponding to the data signal VDATA is supplied to the light emitting element LE and, thus, the light emitting element LE may emit light with a luminance corresponding to the data signal VDATA.

The first capacitor PC may be electrically connected between the first node N1 and the second node N2.

The first capacitor PC may be charged based on the data signal VDATA transmitted to the first node N1.

Because the first capacitor PC is electrically connected to the gate electrode of the first transistor T1 through the first node N1, the turn-on state of the first transistor T1 may be maintained for a duration corresponding to the voltage charged in the first capacitor PC.

The third transistor T3 may be electrically connected between the initialization voltage line VIL and the second node N2.

The gate electrode of the third transistor T3 may be electrically connected to the initialization gate line IGL. For example, the third transistor T3 may be turned on by the initialization control signal ICS of the initialization gate line IGL.

When the third transistor T3 is turned on, the potential of the second node N2, e.g., the potential of the anode electrode of the light emitting element LE, may be initialized to the initialization voltage VINT of the initialization voltage line VIL.

In one or more embodiments, FIG. 5 illustrates that the light emitting pixel driver EPD has a three-transistor one-capacitor (3T1C) structure including the first transistor T1, the second transistor T2, the third transistor T3, and the first capacitor PC, but this is merely an example. For example, the light emitting pixel driver EPD according to one or more embodiments is not limited to the 3T1C structure shown in FIG. 5, and it may be modified differently from that shown in FIG. 5 as needed. In one example, the light emitting pixel driver EPD may not include (e.g., may exclude) the third transistor T3. In another example, the light emitting pixel driver EPD may further include a transistor for initializing the potential of the first node N1.

Additionally, as shown in FIG. 5, each of the first, second, and third transistors T1, T2, and T3 may be an N-type (kind) metal oxide semiconductor field effect transistor (MOSFET). However, this is merely an example, and at least one of the first, second, or third transistor T1, T2, or T3 may be a P-type (kind) MOSFET. FIG. 6 is a layout diagram illustrating part B of FIG. 2.

Referring to FIG. 6, the display area DA in the substrate 11 of the display device 1 according to one or more embodiments may include the emission areas EA arranged side by side and a non-emission area NEA that is a separation area between the emission areas EA.

The element layer 13 (see FIG. 3) may include the light emitting elements LE (see FIG. 5) respectively arranged in the emission areas EA.

The emission areas EA may have a rhombic shape or a rectangular shape in a plan view. However, this is only an example, and the planar shape of the emission areas EA according to one or more embodiments is not limited to that illustrated in FIG. 6. For example, in a plan view, the emission areas EA may have a polygonal shape such as a quadrangle, a pentagon, or a hexagon, or may have a circular or elliptical shape including a curved edge.

According to one or more embodiments, the emission areas EA may include a first emission area EA1 that emits light in a first wavelength band, a second emission area EA2 that emits light in a second wavelength band lower than the first wavelength band, and a third emission area EA3 that emits light in a third wavelength band lower than the second wavelength band.

For example, the first wavelength band may be about 600 nm to about 750 nm, and the light in the first wavelength band may be red light. The second wavelength band is about 480 nm to about 560 nm, and light in the second wavelength band may be green light. The third wavelength band is about 370 nm to about 460 nm, and light in the third wavelength band may be blue light.

The first emission areas EA1 and the third emission areas EA3 may be alternately arranged in the first direction DR1 or the second direction DR2.

The second emission area EA2 may be arranged parallel to each other in the first direction DR1 or the second direction DR2.

The second emission areas EA2 may be adjacent to the first emission areas EA1 and the third emission areas EA3 in diagonal directions crossing the first direction DR1 and the second direction DR2.

Pixels PX displaying their own luminances and colors may be provided by the first emission area EA1, the second emission area EA2, and the third emission area EA3 adjacent to each other among these emission areas EA.

The pixels PX may be a basic unit for displaying various colors including white with a set or predetermined luminance.

Each of the pixels PX may include at least one first emission area EA1, at least one second emission area EA2, and at least one third emission area EA3 that are adjacent to each other. Accordingly, each of the pixels PX may display one or more suitable colors through a mixture of the light emitted from the first emission area EA1, the second emission area EA2, and the third emission area EA3 that are adjacent to each other.

According to one or more embodiments, each of the emission areas EA may include a main emission area MEA arranged at the center, and a sub-emission area SEA around (e.g., surrounding) the main emission area MEA.

The main emission area MEA may be an area where light is emitted in the third direction DR3, in which the first substrate 10 and the second substrate 20 face each other.

The sub-emission area SEA may be an area where light is emitted in an oblique direction with respect to the third direction DR3.

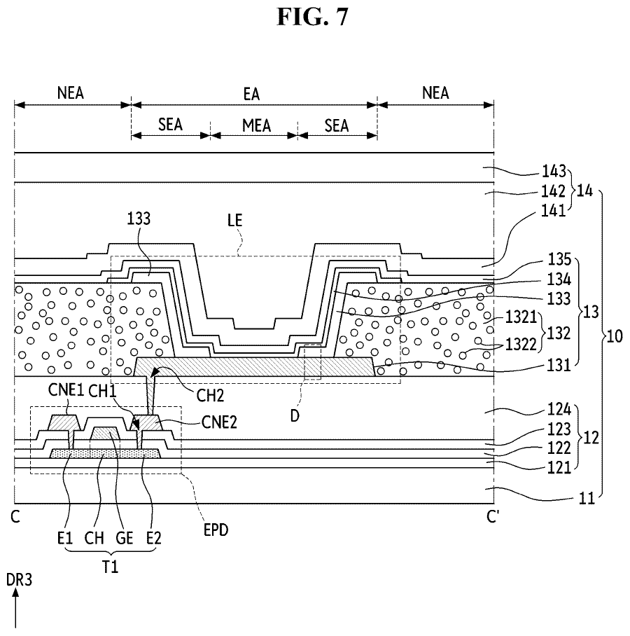

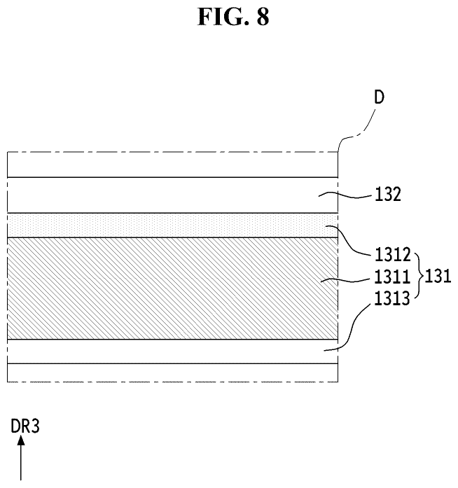

FIG. 7 is a cross-sectional view taken along the line C-C′ of FIG. 6 according to one or more embodiments. FIG. 8 is an enlarged view showing part D of FIG. 7. Referring to FIG. 7, the first substrate 10 of the display device 1 according to one or more embodiments includes the substrate 11, the circuit layer 12 arranged on the substrate 11, and the element layer 13 arranged on the circuit layer 12.

The first substrate 10 of the display device 1 may further include an encapsulation layer 14 arranged on the element layer 13.

The substrate 11 may include the display area DA that includes the emission areas EA arranged side by side and the non-emission area NEA arranged between them.

The circuit layer 12 may include a buffer layer 121 arranged on the substrate 11, a semiconductor layer (including a channel portion CH, a first electrode portion E1, and a second electrode portion E2) arranged on the buffer layer 121, a gate insulating layer 122 covering the semiconductor layer, a gate conductive layer (including a gate electrode GE) arranged on the gate insulating layer 122, an interlayer insulating layer 123 covering the gate conductive layer, a source-drain conductive layer (including a first connection electrode CNE1 and a second connection electrode CNE2) arranged on the interlayer insulating layer 123, and a planarization layer 124 covering the source-drain conductive layer.

Each of the buffer layer 121 and the gate insulating layer 122 may include an inorganic insulating material.

Each of the interlayer insulating layer 123 and the planarization layer 124 may include an inorganic insulating material or an organic insulating material.

The circuit layer 12 may include the light emitting pixel drivers EPD respectively corresponding to the emission areas EA.

Each of the light emitting pixel drivers EPD may include the first transistor T1 that generates the driving current Ids (see FIG. 5) for the light emitting element LE.

The first transistor T1 may include the channel portion CH, the first electrode portion E1, and the second electrode portion E2 arranged in the semiconductor layer on the buffer layer 121, and the gate electrode GE arranged in the gate conductive layer on the gate insulating layer 122.

The first electrode portion E1 may be connected to one side of the channel portion CH.

The second electrode portion E2 may be connected to the other side of the channel portion CH.

The gate electrode GE may overlap the channel portion CH.

The first connection electrode CNE1 may be electrically connected to the first electrode portion E1 of the first transistor T1. In one example, the first electrode portion E1 of the first transistor T1 may be electrically connected to the first power line VDL (see FIG. 5) through the first connection electrode CNE1.

The second connection electrode CNE2 may be electrically connected to the second electrode portion E2 of the first transistor T1 through the first connection hole CH1.

The element layer 13 may include the light emitting elements LE arranged in the emission areas EA.

Each of the emission areas EA may include the main emission area MEA and the sub-emission area SEA around (e.g., surrounding) the main emission area MEA, and may be surrounded by the non-emission area NEA.

As shown in FIG. 7, according to one or more embodiments, the light emitting element LE arranged in one of the emission areas EA may include a first electrode 131 arranged in the emission area EA, a pixel defining layer 132 arranged in the non-emission area NEA and extending into the sub-emission area SEA of the one emission area EA, a scattering auxiliary electrode 133 arranged on the pixel defining layer 132, overlapping the sub-emission area SEA of the one emission area EA, and electrically connected to the first electrode 131, a light emitting layer 134 arranged on the first electrode 131 and the scattering auxiliary electrode 133, and a second electrode 135 arranged on the pixel defining layer 132 and the light emitting layer 134.

For example, the element layer 13 may include the first electrodes 131 arranged in the emission areas EA, the pixel defining layer 132 arranged in the non-emission area NEA and the sub-emission areas SEA of the emission areas EA, the scattering auxiliary electrodes 133 arranged on the pixel defining layer 132, overlapping the sub-emission areas SEA of the emission areas EA, and electrically connected to the first electrodes 131, the light emitting layer 134 arranged on the first electrodes 131 and the scattering auxiliary electrodes 133 and overlapping the emission areas EA, and the second electrode 135 arranged on the pixel defining layer 132 and the light emitting layers 134.

The first electrode 131 may be arranged on the planarization layer 124 of the circuit layer 12, and may overlap the emission area EA.

The first electrode 131 may be electrically connected to the second connection electrode CNE2 through a second connection hole CH2. As a result, the first electrode 131 may be electrically connected to the first transistor T1 of the light emitting pixel driver EPD. The first electrode 131 may be a pixel electrode or an anode electrode.

Referring to FIG. 8, the first electrode 131 according to one or more embodiments may include a reflective portion 1311 that reflects light, and a roof portion 1312 arranged on the reflective portion 1311.

The reflective portion 1311 may contain a reflective metallic material (e.g., may be formed of a reflective metal).

For example, the reflective portion 1311 may include (e.g., be) silver (Ag) or an alloy containing silver (Ag).

The roof portion 1312 may be arranged on the top surface of the reflective portion 1311.

The roof portion 1312 may be intended to protect the top surface of the reflective portion 1311 so that it is not directly exposed to heat treatment or etching material.

The roof portion 1312 may contain a crystalline transparent conductive material to have a relatively high etching rate.

In one example, the roof portion 1312 may contain crystalline indium tin oxide (ITO) that has been crystallized by being repeatedly exposed to heat treatment or etching material.

The first electrode 131 may further include a bottom portion 1313 arranged on the rear surface of the reflective portion 1311 and opposite the roof portion 1312.

The bottom portion 1313 may contain a transparent conductive material. In one example, the bottom portion 1313 may contain indium tin oxide (ITO).

As shown in FIG. 7, the pixel defining layer 132 may be arranged on the planarization layer 124 of the circuit layer 12 and may extend into the non-emission area NEA and the sub-emission area SEA of the emission area EA.

A portion of the pixel defining layer 132 in the non-emission area NEA may be arranged with a relatively substantially uniform thickness.

In contrast, another portion of the pixel defining layer 132 arranged in the sub-emission area SEA may have a thickness that gradually decreases as it approaches the main emission area MEA. For example, another portion of the pixel defining layer 132 arranged in the sub-emission area SEA may include an inclined surface that is sloped (e.g., with an angle of greater than 0° and less than) 90° with respect to the first electrode 131.

The pixel defining layer 132 may contain a light-transmitting organic insulating material 1321 and scattering particles 1322 dispersed in the organic insulating material 1321.

Each of the scattering particles 1322 may be a metal oxide particle, a hollow silica particle, and/or a porogen.

The metal oxide particle may contain at least one of titanium oxide (TiO₂) or zirconium oxide (ZrO).

According to one or more embodiments, the scattering auxiliary electrode 133 may be arranged on another portion of the pixel defining layer 132 arranged in the sub-emission area SEA.

The scattering auxiliary electrode 133 may contain a transparent conductive material.

For example, the scattering auxiliary electrode 133 may contain at least one of indium tin oxide (ITO), indium zinc oxide (IZO), or indium gallium zinc oxide (IGZO).

Because the scattering auxiliary electrode 133 overlaps the sub-emission area SEA, it may be arranged on the inclined surface of the pixel defining layer 132.

The scattering auxiliary electrode 133 may extend to the first electrode 131 and may be in contact with at least a portion of the first electrode 131.

According to one or more embodiments, the scattering auxiliary electrode 133 may be in contact with a portion of the first electrode 131.

The light emitting layer 134 may overlap one emission area EA and may be arranged on the first electrode 131 and the scattering auxiliary electrode 133.

The second electrode 135 may be arranged across the entire display area DA (see FIGS. 4 and 6) including the emission areas EA and the non-emission area NEA. The second electrode 135 may be a common electrode or a cathode electrode.

The second electrode 135 may contain a transparent conductive material.

For example, the second electrode 135 may contain at least one of indium tin oxide (ITO), indium zinc oxide (IZO), or indium gallium zinc oxide (IGZO).

The encapsulation layer 14 is to block the permeation of oxygen and/or moisture into the element layer 13 and to reduce electrical and/or physical impact to the circuit layer 12 and the element layer 13.

The encapsulation layer 14 may include a first encapsulation layer 141 arranged on the element layer 13 and containing an inorganic insulating material, a second encapsulation layer 142 arranged on the first encapsulation layer 141, overlapping the display area DA, and containing an organic insulating material, and a third encapsulation layer 143 covering the second encapsulation layer 142 and containing an inorganic insulating material.

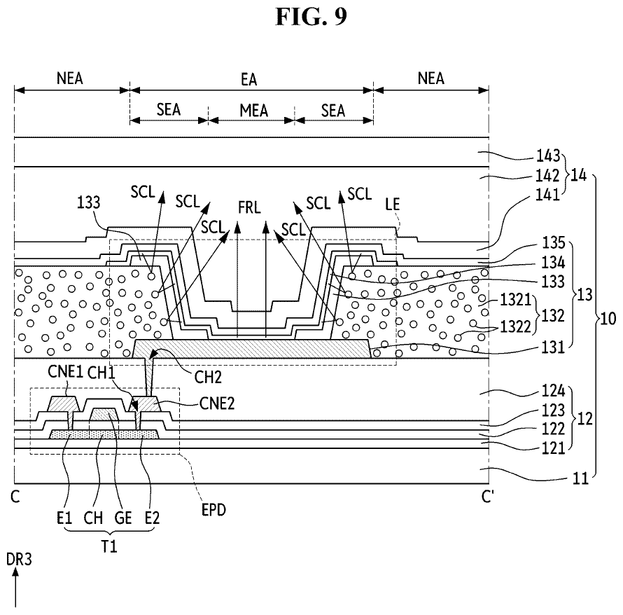

FIG. 9 is a diagram illustrating the light emission direction of the light emitting element of FIG. 7.

Referring to FIG. 9, the light emitting element LE according to embodiments illustrated in FIG. 7 includes the scattering auxiliary electrode 133, which is arranged on a portion of the pixel defining layer 132 overlapping the sub-emission area SEA, and the pixel defining layer 132 contains the scattering particles 1322.

Accordingly, in the main emission area MEA of the emission area EA, light from the light emitting layer 134 may be reflected by the first electrode 131 and emitted as front light FRL directed in a front direction relatively parallel to the third direction DR3.

In contrast, in the sub-emission area SEA of the emission area EA, light from the light emitting layer 134 may be scattered in an irregular direction (e.g., a random direction) by the scattering particles 1322 of the pixel defining layer 132 and emitted as scattered light SCL directed in a side direction oblique to the third direction DR3.

Therefore, the light amount of the front light FRL may be maintained above a threshold, so that the viewing angle, representing a range within which the display device 1 can be observed with a luminance above the threshold, may be improved by the scattered light SCL, without significantly degrading the display quality of the display device 1.

Additionally, because the scattering auxiliary electrode 133 is arranged on the inclined surface of the pixel defining layer 132, the surface area where the scattering auxiliary electrode 133 and the second electrode 135 face each other may be larger than the surface area of the sub-emission area SEA. For example, the light amount of the light emitting element LE may not be limited by the surface area of the emission area EA, and thus the luminance of the light emitting element LE may be improved.

Table 1 shows, in the light emitting element LE according to one or more embodiments, the simulation results of the ratio of the front light FRL and the scattered light SCL to the total amount of light emitted from the light emitting element LE, based on the proportion of the sub-emission area SEA within the emission area EA.

TABLE 1

| Proportion of sub- | Ratio of front | Ratio of scattered |
|---|---|---|
| emission area (SEA) | light (FRL) | light (SCL) |
| 53% | 87% | 60% |
| 71% | 74% | 70% |
| 80% | 67% | 76% |

According to the simulation results of Table 1, it may be observed that if (e.g., when) the proportion of the sub-emission area SEA within the emission area EA is 80% or less, the ratio of the front light FRL to the total amount of light emitted from the light emitting element LE is maintained at about 60% or more, while the ratio of the scattered light SCL also reaches about 60% or more.

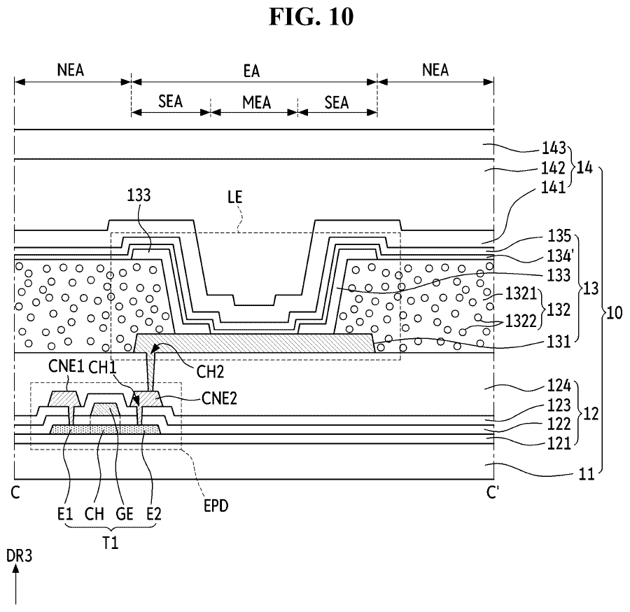

FIGS. 10, 11, 12 and 13 are cross-sectional views cut along the line C-C′ of FIG. 6 according to embodiments, respectively.

The light emitting element LE of the display device 1 according to one or more embodiments shown in FIG. 10 is substantially the same as the light emitting element LE according to the embodiments shown in FIG. 7, except that a light emitting layer 134′ is arranged not only in the emission areas EA but also in the non-emission area NEA, and thus a redundant description will not be provided.

The element layer 13 according to one or more embodiments of FIG. 7 may include the light emitting layers 134 respectively arranged in the emission areas EA.

In contrast, the element layer 13 according to one or more embodiments of FIG. 10 may include the light emitting layer 134′ arranged across the entire display area DA including the emission areas EA and the non-emission area NEA.

In this way, the light emitting elements LE of the element layer 13 may be to emit light in substantially the same wavelength band.

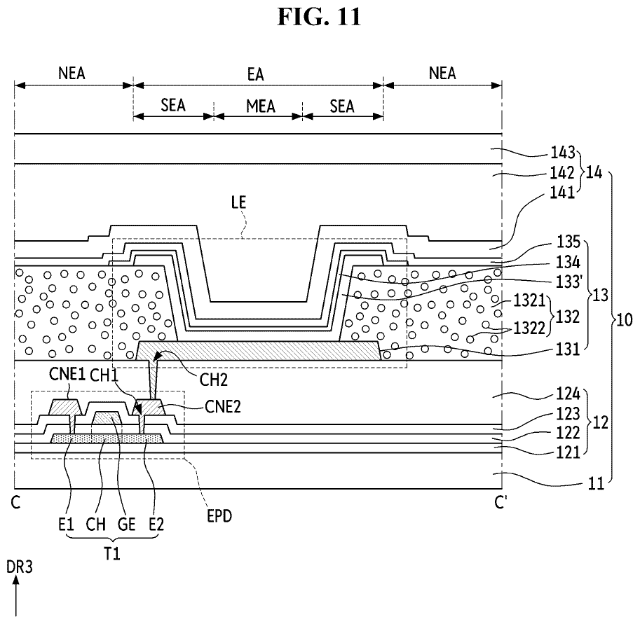

The light emitting element LE of the display device 1 according to one or more embodiments shown in FIG. 11 is substantially the same as the light emitting element LE according to the embodiments shown in FIG. 7, except that a scattering auxiliary electrode 133′ is in contact with the first electrode 131 in the entire main emission area MEA, rather than in a portion of the main emission area MEA, and thus a redundant description will not be provided.

According to one or more embodiments of FIG. 11, as the scattering auxiliary electrode 133′ is arranged in the emission area EA, similarly to the first electrode 131, it may entirely cover the first electrode 131 in the main emission area MEA.

In this way, the electrical connection between the first electrode 131 and the scattering auxiliary electrode 133′ may be strengthened. Additionally, because fluctuations in micro-resonance conditions due to the presence or absence of the scattering auxiliary electrode 133′ may be reduced or eliminated, the uniformity of the color purity and light emission efficiency of the light emitting element LE may be improved.

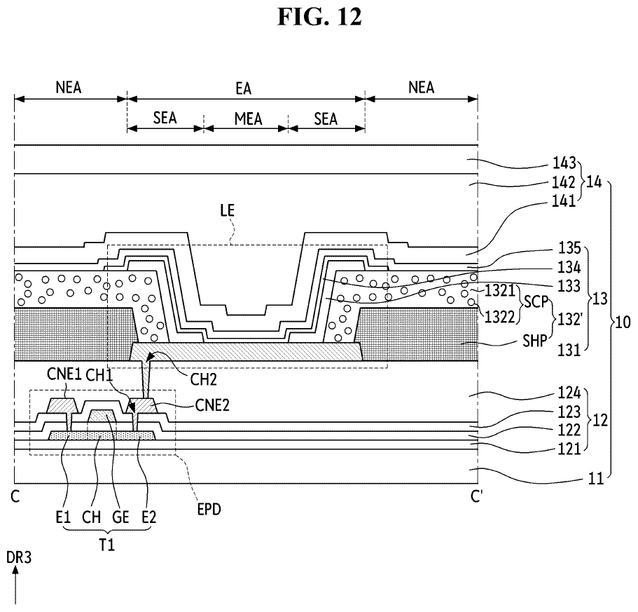

The light emitting element LE of the display device 1 according to one or more embodiments shown in FIG. 12 is substantially the same as the light emitting element LE according to the embodiments shown in FIG. 7, except that a pixel defining layer 132′ includes a light blocking portion SHP and a scattering portion SCP, and thus a redundant description will not be provided.

According to one or more embodiments of FIG. 12, the pixel defining layer 132′ may include the light blocking portion SHP arranged in the non-emission area NEA and containing a light-blocking organic material, and the scattering portion SCP covering the light blocking portion SHP and containing the light-transmitting organic insulating material 1321 and the scattering particles 1322 dispersed therein.

The scattering auxiliary electrode 133 may be arranged on the scattering portion SCP.

In this way, the scattered light SCL (see FIG. 9) may be emitted from the sub-emission area SEA by the scattering portion SCP of the pixel defining layer 132′, while light leakage from the non-emission area NEA may be reduced by the light blocking portion SHP of the pixel defining layer 132′.

Accordingly, the display quality of the display device 1 may be further improved.

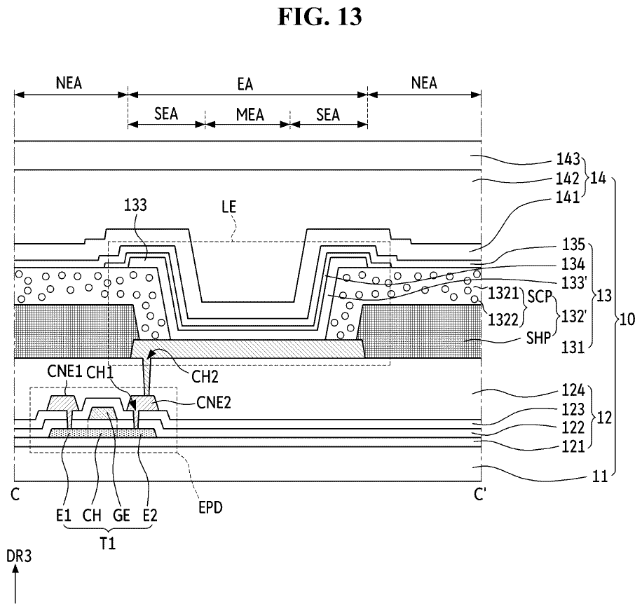

The light emitting element LE of the display device 1 according to one or more embodiments shown in FIG. 13 is substantially the same as the light emitting element LE according to one or more embodiments shown in FIG. 12, except that the scattering auxiliary electrode 133′ is in contact with the first electrode 131 in the entire main emission area MEA, and thus a redundant description will not be provided.

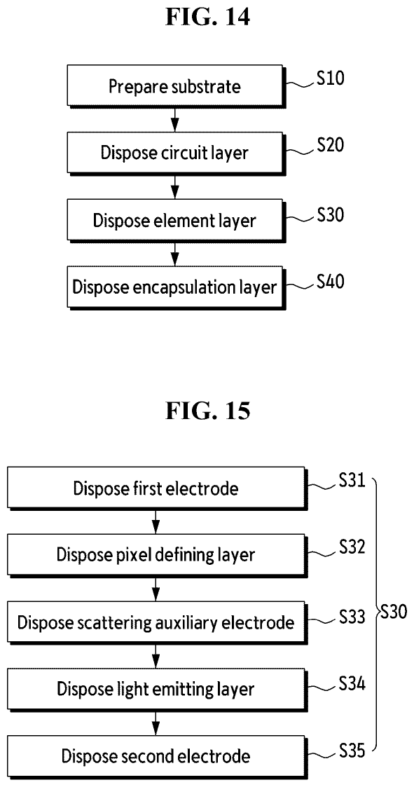

FIG. 14 is a flowchart illustrating a method for manufacturing the display device according to one or more embodiments. FIG. 15 is a flowchart illustrating a step (e.g., act or task) of disposing an element layer shown in FIG. 14.

Referring to FIG. 14, a method for manufacturing the display device 1 according to one or more embodiments may include preparing the substrate 11 including the emission areas EA and the non-emission area NEA (step (e.g., act or task) S10), disposing the circuit layer 12 on the substrate 11 (step (e.g., act or task) S20), and disposing the element layer 13 on the circuit layer 12 (step (e.g., act or task) S30).

The method for manufacturing the display device 1 may further include disposing the encapsulation layer 14 on the element layer 13 (step (e.g., act or task) S40).

Referring to FIG. 15, step (e.g., act or task) S30 of disposing the element layer 13 may include disposing the first electrodes 131 in the emission areas EA (step (e.g., act or task) S31), disposing the pixel defining layer 132 in the non-emission area NEA and the sub-emission areas SEA of the emission areas EA (step (e.g., act or task) S32), disposing, on the pixel defining layer 132, the scattering auxiliary electrodes 133 overlapping the sub-emission areas SEA of the emission areas EA and electrically connected to the first electrodes 131 (step (e.g., act or task) S33), disposing the light emitting layers 134 overlapping the emission areas EA on the first electrodes 131 and the scattering auxiliary electrodes 133 (step (e.g., act or task) S34), and disposing the second electrode 135 on the pixel defining layer 132 and the light emitting layers 134 (step (e.g., act or task) S35).

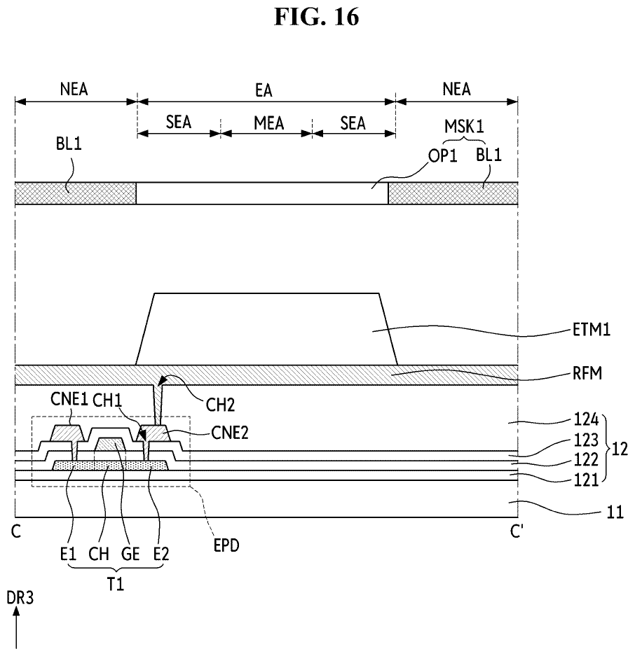

FIGS. 16 to 23 are process diagrams illustrating some (e.g., acts or tasks) steps of FIG. 15 according to the embodiments illustrated in FIG. 7.

Referring to FIG. 16, step (e.g., act or task) S31 of disposing the first electrodes 131 may include a process of disposing a reflective conductive material layer RFM on the planarization layer 124 of the circuit layer 12, and a process of disposing first etching masks ETM1 on the reflective conductive material layer RFM using a first mask MSK1.

As shown in FIG. 8, the reflective conductive material layer RFM may include the reflective portion 1311 that reflects light, and the roof portion 1312 arranged on the reflective portion 1311.

The reflective portion 1311 may contain a reflective metallic material (e.g., may be formed of a reflective metal).

The roof portion 1312 may contain a crystalline transparent conductive material.

As shown in FIG. 16, the first mask MSK1 may include first openings OP1 opposite to (e.g., facing) the emission areas EA, and a first blocking portion BL1 opposite to (e.g., facing) the non-emission area NEA.

By the first openings OP1 of the first mask MSK1, the first etching masks ETM1 may be arranged (e.g., formed) in the emission areas EA on the reflective conductive material layer RFM.

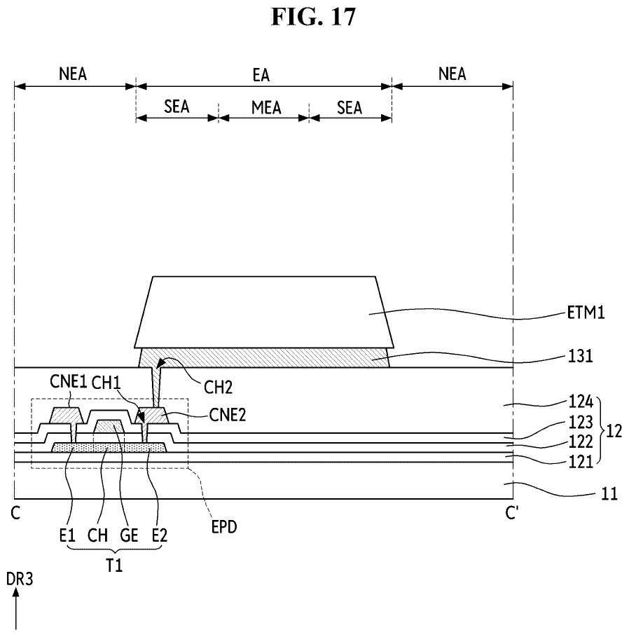

As shown in FIG. 17, step (e.g., act or task) S31 of disposing the first electrodes 131 may include a process of disposing the first electrodes 131 by partially removing the reflective conductive material layer RFM using the first etching masks ETM1.

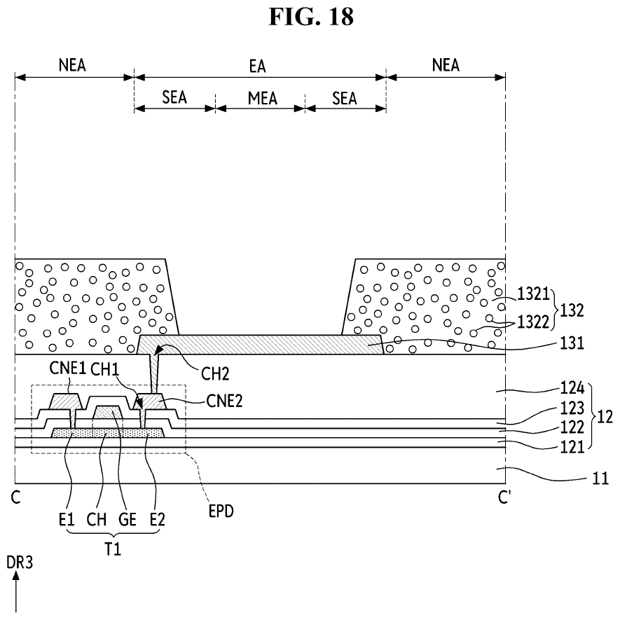

As shown in FIG. 18, in step (e.g., act or task) S32 of disposing the pixel defining layer 132, the pixel defining layer 132 may be arranged (e.g., formed) by partially disposing a scattering material layer containing the light-transmitting organic insulating material 1321 and the scattering particles 1322 dispersed therein.

The pixel defining layer 132 may be arranged in the non-emission area NEA and extend into the sub-emission areas SEA of the emission areas EA.

A portion of the pixel defining layer 132 arranged in the sub-emission areas SEA of the emission areas EA may include an inclined surface that is sloped (e.g., with an angle of greater than 0° and less than) 90° with respect to the first electrode 131.

Each of the scattering particles 1322 may be a metal oxide particle, a hollow silica particle, and/or a porogen.

The metal oxide particle may contain at least one of titanium oxide (TiO₂) or zirconium oxide (ZrO).

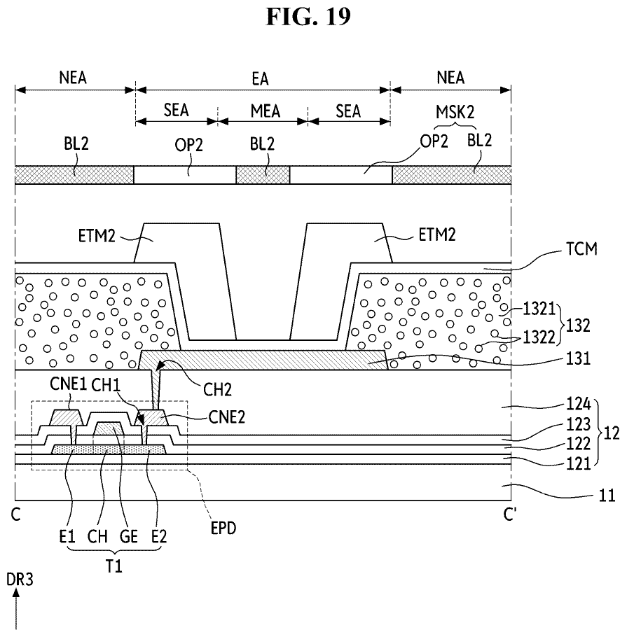

As shown in FIG. 19, step (e.g., act or task) S33 of disposing the scattering auxiliary electrodes 133 may include a process of disposing a transparent conductive material layer TCM covering the first electrodes 131 and the pixel defining layer 132, and a process of disposing second etching masks ETM2 on the transparent conductive material layer TCM using a second mask MSK2.

The transparent conductive material layer TCM may contain at least one of indium tin oxide (ITO), indium zinc oxide (IZO), or indium gallium zinc oxide (IGZO).

The second mask MSK2 may include second openings OP2 opposite to (e.g., facing) the sub-emission areas SEA of the emission areas EA, and a second blocking portion BL2 opposite to (e.g., facing) the non-emission area NEA and the main emission areas MEA of the emission areas EA.

By the second openings OP2 of the second mask MSK2, the second etching masks ETM2 opposite to (e.g., facing) the sub-emission areas SEA of the emission areas EA may be arranged on the transparent conductive material layer TCM.

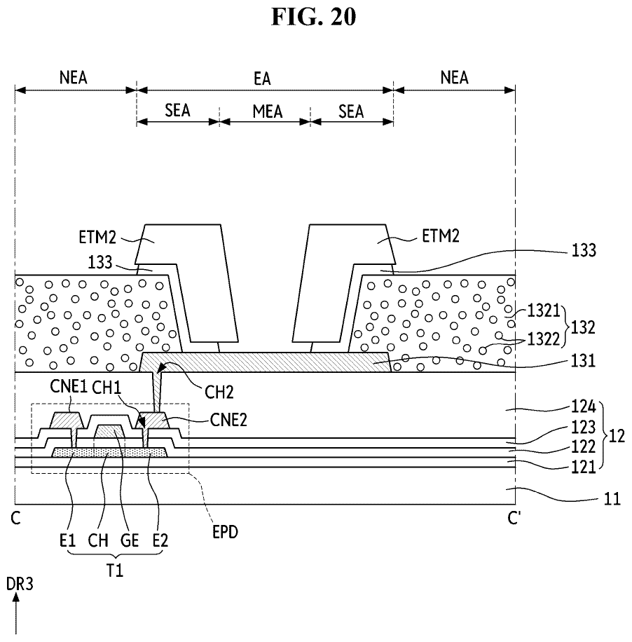

As shown in FIG. 20, step (e.g., act or task) S33 of disposing the scattering auxiliary electrodes 133 may include a process of disposing the scattering auxiliary electrodes 133 by partially removing the transparent conductive material layer TCM using the second etching masks ETM2.

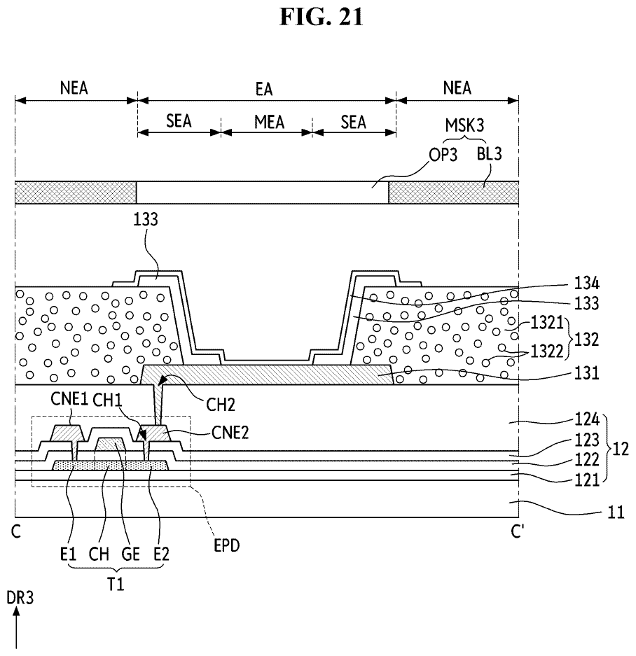

As shown in FIG. 21, in step (e.g., act or task) S34 of disposing the light emitting layers 134, the light emitting layers 134 may be arranged (e.g., formed) by partially depositing an organic light emitting material using a third mask MSK3.

The third mask MSK3 may include third openings OP3 opposite to (e.g., facing) the emission areas EA and a third blocking portion BL3 opposite to (e.g., facing) the non-emission area NEA.

The third mask MSK3 may be provided in three types (kinds) corresponding to the first emission areas EA1 (see FIG. 6), the second emission areas EA2 (see FIG. 6), and the third emission areas EA3 (see FIG. 6).

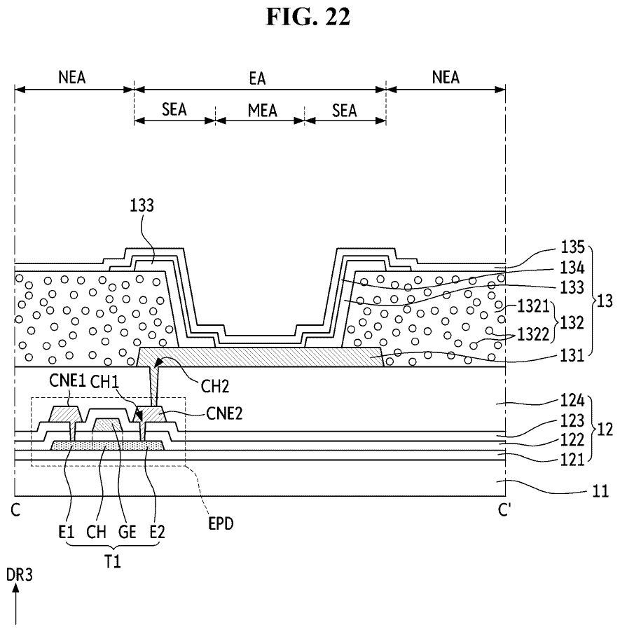

As shown in FIG. 22, in step (e.g., act or task) S35 of disposing the second electrode 135, the second electrode 135 may be arranged (e.g., formed) by stacking (e.g., depositing) a transparent conductive material in the display area DA.

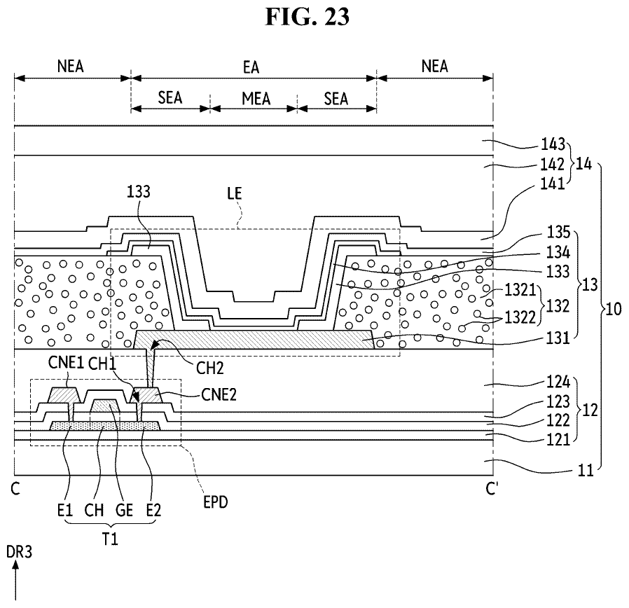

As shown in FIG. 23, step (e.g., act or task) S40 of disposing the encapsulation layer 14 may include a process of disposing the first encapsulation layer 141 by stacking (e.g., depositing) an inorganic insulating material, a process of disposing the second encapsulation layer 142 by depositing, spreading, and curing an organic insulating material, and a process of disposing the third encapsulation layer 143 by stacking (e.g., depositing) an inorganic insulating material.

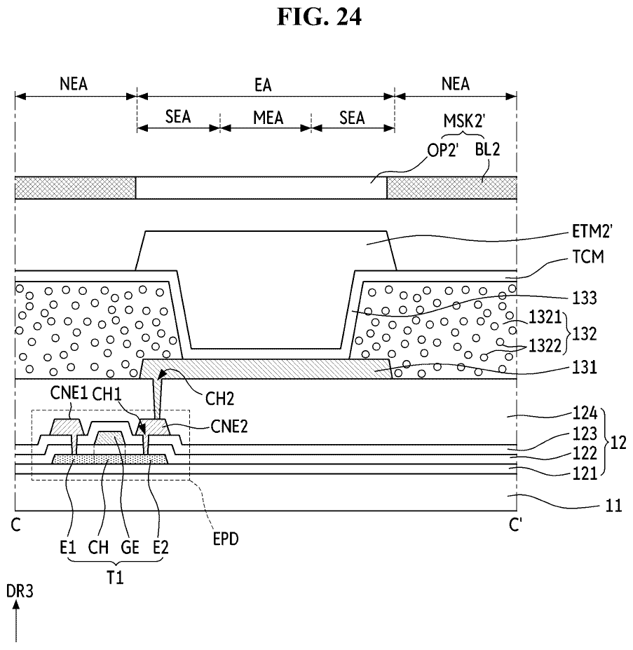

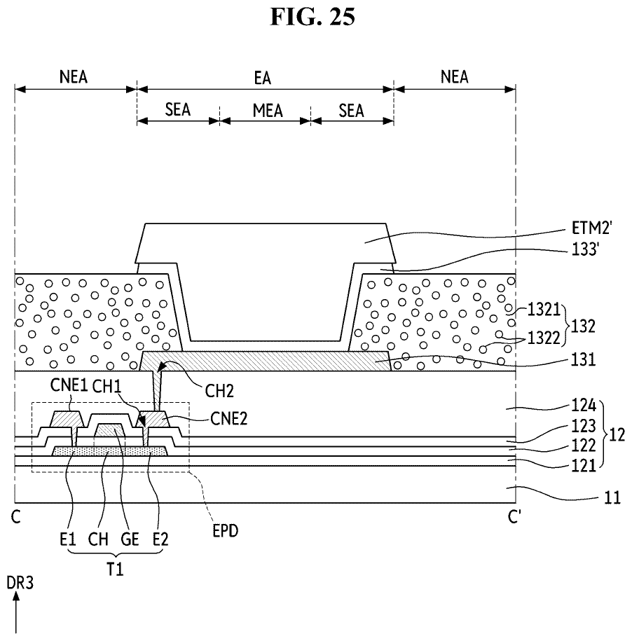

FIGS. 24 and 25 are process diagrams illustrating a step (e.g., act or task) of disposing the scattering auxiliary electrode of FIG. 15, according to the embodiments illustrated in FIG. 11.

As shown in FIG. 24, in step (e.g., act or task) S33 of disposing the scattering auxiliary electrode 133′ in the method for manufacturing the display device 1 according to the embodiments illustrated in FIG. 11, second openings OP2′ of a second mask MSK2′ may face the emission areas EA.

Accordingly, second etching masks ETM2′ on the transparent conductive material layer TCM may be arranged in the emission areas EA.

As shown in FIG. 25, in step (e.g., act or task) S33 of disposing the scattering auxiliary electrode 133′ in the method for manufacturing the display device 1 according to the embodiments illustrated in FIG. 11, the scattering auxiliary electrode 133′ may be arranged in each of the emission areas EA, so that the first electrode 131 of the main emission area MEA may be entirely covered by the scattering auxiliary electrode 133′.

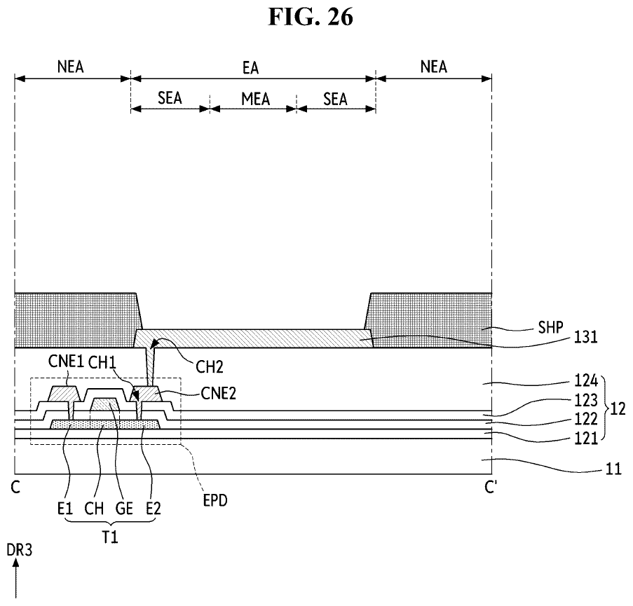

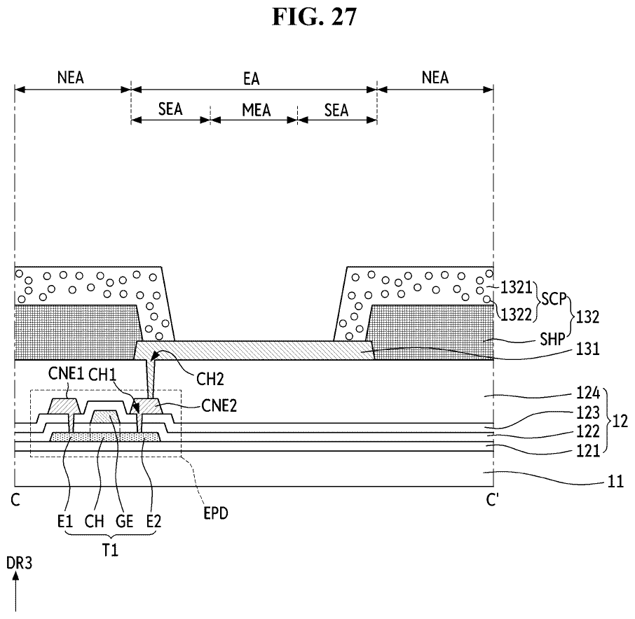

FIGS. 26 and 27 are process diagrams illustrating a step (e.g., act or task) of disposing the pixel defining layer of FIG. 15 according to the embodiments illustrated in FIG. 12.

As shown in FIG. 26, step (e.g., act or task) S32 of disposing the pixel defining layer 132′ in the method for manufacturing the display device 1 according to the embodiments illustrated in FIG. 12 may include a process of disposing the light blocking portion SHP containing a light-blocking organic material in the non-emission area NEA.

As shown in FIG. 27, step (e.g., act or task) S32 of disposing the pixel defining layer 132′ in the method for manufacturing the display device 1 according to the embodiments illustrated in FIG. 12 may include a process of disposing the scattering portion SCP covering the light blocking portion SHP.

The scattering portion SCP may contain the light-transmitting organic insulating material 1321 and the scattering particles 1322 dispersed therein.

The display device according to one or more embodiments of the present disclosure can be applied to one or more suitable electronic devices. The electronic device according to the one or more embodiments of the present disclosure includes the display device described above, and may further include modules or devices having additional functions in addition to the display device.

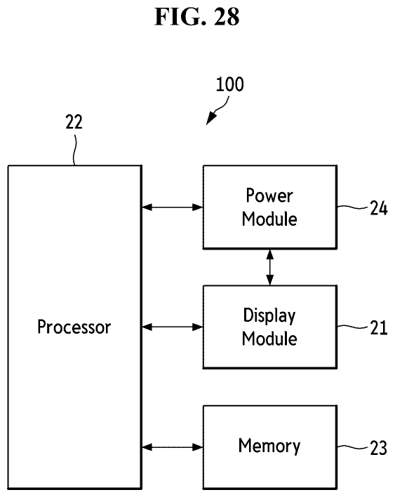

FIG. 28 is a block diagram of an electronic device according to one or more embodiments of the present disclosure.

Referring to FIG. 28, the electronic device 100 according to one or more embodiments of the present disclosure may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), or a controller.

The memory 23 may store data information necessary for the operation of the processor 22 or the display module 21. When the processor 22 executes an application stored in the memory 23, an image data signal and/or an input control signal is transmitted to the display module 21, and the display module 21 can process the received signal and output image information through a display screen.

The power module 24 may include a power supply module such as, for example a power adapter or a battery, and a power conversion module that converts the power supplied by the power supply module to generate power necessary for the operation of the electronic device 100.

At least one of the components of the electronic device 100 according to the one or more embodiments of the present disclosure may be included in the display device 1 according to one or more embodiments of the present disclosure. In addition, some modules of the individual modules functionally included in one module may be included in the display device 1, and other modules may be provided separately from the display device 1. For example, the display device 1 may include the display module 21, and the processor 22, the memory 23, and the power module 24 may be provided in the form of other devices within the electronic device 100 other than the display device 1.

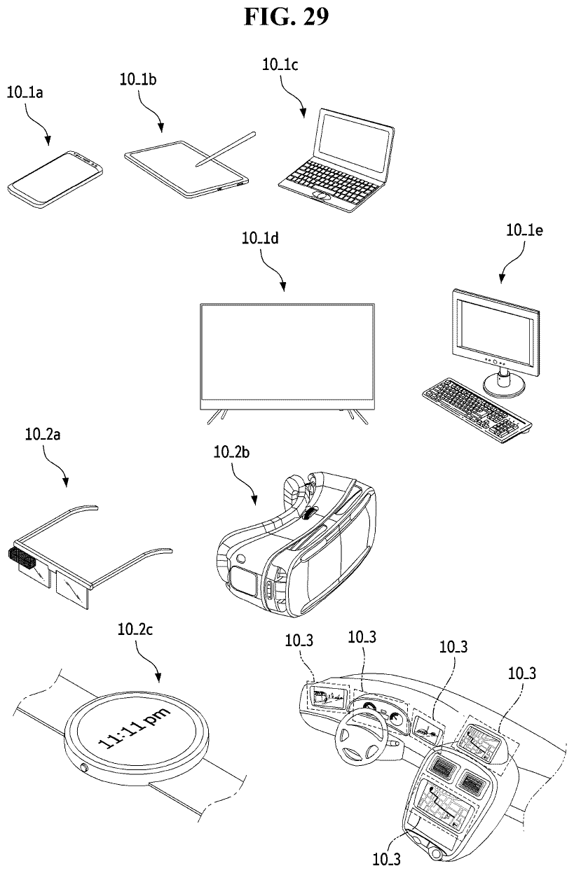

FIG. 29 is a schematic diagram of electronic devices according to embodiments of the present disclosure.

Referring to FIG. 29, electronic devices to which display devices 1 according to embodiments of the present disclosure are applied may include not only image display electronic devices such as a smart phone 10_1a, a tablet PC (personal computer) 10_1b, a laptop 10_1c, a TV 10_1d, and a desk monitor 10_1e, but also wearable electronic devices including display modules such as, for example smart glasses 10_2a, a head mounted display 10_2b, and a smart watch 10_2c, and vehicle electronic devices 10_3 including display modules such as a CID (Center Information Display) and a room mirror display arranged on a dashboard, center fascia, and/or dashboard of an automobile.

In the context of the present application and unless otherwise defined, the terms “use,” “using,” and “used” may be considered synonymous with the terms “utilize,” “utilizing,” and “utilized,” respectively. Also, the terms “disposing,” “arranging,” and variations thereof, may be used interchangeably with terms “depositing,” “applying,” “laminating,” “attaching,” “placing,” and variations thereof.

The use of “may” when describing embodiments of the inventive concept refers to “one or more embodiments of the inventive concept.”

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

A display device, an electronic device, a device for manufacturing the same, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

However, the effects of the present disclosure are not restricted to the one set forth herein. The above and other effects of the present disclosure will become more apparent to one of ordinary skill in the art to which the present disclosure pertains by referencing the claims, and equivalents thereof.

What is claimed is:

1. A light emitting element comprising:
a first electrode in an emission area, the emission area comprising a main emission area and a sub-emission area around the main emission area;
a pixel defining layer in a non-emission area around the emission area and extending into the sub-emission area;
a scattering auxiliary electrode on the pixel defining layer, overlapping the sub-emission area, and electrically connected to the first electrode;
a light emitting layer on the first electrode and the scattering auxiliary electrode; and
a second electrode on the pixel defining layer and the light emitting layer.

2. The light emitting element of claim 1, wherein
the pixel defining layer comprises a light-transmitting organic insulating material, and scattering particles dispersed in the organic insulating material,
each of the scattering particles is a metal oxide particle, a hollow silica particle, or a porogen, and
the metal oxide particle comprises titanium oxide (TiO₂) and/or zirconium oxide (ZrO).

3. The light emitting element of claim 2, wherein the pixel defining layer in the sub-emission area has an inclined surface that is sloped relative to the first electrode.

4. The light emitting element of claim 3, wherein the scattering auxiliary electrode is on the inclined surface of the pixel defining layer, extends to the first electrode, and is in contact with at least a portion of the first electrode.

5. The light emitting element of claim 4, wherein the scattering auxiliary electrode entirely covers the first electrode in the main emission area.

6. The light emitting element of claim 4, wherein the first electrode comprises:
a reflective portion configured to reflect light; and
a roof portion on the reflective portion,
wherein the roof portion comprises a crystalline transparent conductive material.

7. The light emitting element of claim 4, wherein the scattering auxiliary electrode comprises a transparent conductive material.

8. The light emitting element of claim 4, wherein the pixel defining layer comprises:
a light blocking portion in the non-emission area and comprising a light-blocking organic material; and
a scattering portion covering the light blocking portion and comprising the organic insulating material and the scattering particles.

9. A display device comprising:
a substrate comprising emission areas and a non-emission area between the emission areas;
a circuit layer on the substrate; and
an element layer on the circuit layer,
wherein each of the emission areas comprises a main emission area and a sub-emission area around the main emission area,
the element layer comprises light emitting elements in the emission areas,
the circuit layer comprises light emitting pixel drivers electrically connected to the light emitting elements, and
the light emitting element in one of the emission areas comprises:
a first electrode in the one emission area;
a pixel defining layer in the non-emission area around the emission area and extending into the sub-emission area of the one emission area;
a scattering auxiliary electrode on the pixel defining layer, overlapping the sub-emission area of the one emission area, and electrically connected to the first electrode;
a light emitting layer on the first electrode and the scattering auxiliary electrode; and
a second electrode on the pixel defining layer and the light emitting layer.

10. The display device of claim 9, wherein
the pixel defining layer comprises a light-transmitting organic insulating material, and scattering particles dispersed in the organic insulating material,
each of the scattering particles is a metal oxide particle, a hollow silica particle, or a porogen, and
the metal oxide particle comprises titanium oxide (TiO₂) and/or zirconium oxide (ZrO).

11. The display device of claim 10, wherein the pixel defining layer in the sub-emission area has an inclined surface that is sloped relative to the first electrode.

12. The display device of claim 11, wherein the scattering auxiliary electrode is on the inclined surface of the pixel defining layer, extends to the first electrode, is in contact with at least a portion of the first electrode, and comprises a transparent conductive material.

13. The display device of claim 12, wherein the scattering auxiliary electrode entirely covers the first electrode in the main emission area.

14. The display device of claim 12, wherein the first electrode comprises:
a reflective portion configured to reflect light; and
a roof portion on the reflective portion,
wherein the roof portion comprises a crystalline transparent conductive material.

15. The display device of claim 12, wherein the pixel defining layer comprises:
a light blocking portion in the non-emission area and comprising a light-blocking organic material; and
a scattering portion covering the light blocking portion and comprising the organic insulating material and the scattering particles.

16. A method for manufacturing the display device of claim 9, the method comprising:
preparing the substrate comprising the emission areas and the non-emission area between the emission areas;
disposing the circuit layer on the substrate; and
disposing the element layer on the circuit layer,
wherein the disposing of the element layer comprises:
disposing the first electrode;
disposing the pixel defining layer;
disposing, on the pixel defining layer, the scattering auxiliary electrode;
disposing the light emitting layer overlapping the emission area on the first electrode and the scattering auxiliary electrode; and
disposing the second electrode.

17. The method of claim 16, wherein in the disposing of the pixel defining layer,
the pixel defining layer comprises a light-transmitting organic insulating material, and scattering particles dispersed in the organic insulating material,
each of the scattering particles is a metal oxide particle, a hollow silica particle, or a porogen, and
the metal oxide particle comprises titanium oxide (TiO₂) and/or zirconium oxide (ZrO).

18. The method of claim 17, wherein
in the disposing of the pixel defining layer, portions of the pixel defining layer, which are in the sub-emission area of the emission area, comprise inclined surfaces that are sloped relative to the first electrode,
in the disposing of the scattering auxiliary electrode, the scattering auxiliary electrode is on the inclined surfaces of the portions of the pixel defining layer, extends to the first electrodes, and comprises a transparent conductive material, and
the scattering auxiliary electrode is in contact with at least a portion of the first electrode.

19. An electronic device comprising a display device, the display device comprising:
a substrate comprising emission areas and a non-emission area between the emission areas;
a circuit layer on the substrate; and
an element layer on the circuit layer,
wherein each of the emission areas comprises a main emission area and a sub-emission area around the main emission area,
the element layer comprises light emitting elements in the emission areas,
the circuit layer comprises light emitting pixel drivers electrically connected to the light emitting elements, and
the light emitting element in one of the emission areas comprises:
a first electrode in the one emission area;
a pixel defining layer in the non-emission area around the emission area and extending into the sub-emission area of the one emission area;
a scattering auxiliary electrode on the pixel defining layer, overlapping the sub-emission area of the one emission area, and electrically connected to the first electrode;
a light emitting layer on the first electrode and the scattering auxiliary electrode; and
a second electrode on the pixel defining layer and the light emitting layer.

20. The electronic device of claim 19, wherein the electronic device comprises a television, a laptop computer, a monitor, a billboard, an Internet-of-Things (IOT) device, a mobile phone, a smartphone, a tablet personal computer (PC), a smart watch, a watch phone, a mobile communication terminal, an electronic notebook, an electronic book, a portable multimedia player (PMP), a navigation device, and/or an ultra-mobile PC (UMPC).
